(19) United States
(12) Patent Application Publication
(10) Pub. No.: US 2015/0171592 A1
(43) Pub. Date: Jun. 18, 2015

(54) MODULATOR INTEGRATED LASER DEVICE

(71) Applicant: Mitsubishi Electric Corporation, Tokyo (JP)

(72) Inventors: Takeshi Yamatoya, Tokyo (JP); Kazuhisa Takagi, Tokyo (JP)

(21) Appl. No.: 14/629,626

(22) Filed: Feb. 24, 2015

Related U.S. Application Data
(62) Division of application No. 13/737,088, filed on Jan. 9, 2013.

(30) Foreign Application Priority Data
Apr. 16, 2012 (JP) 2012-092904

(51) Int. Cl. H01S 5/00

(52) U.S. Cl. CPC H01S 5/0085

(57) ABSTRACT

An integrated optical modulator and laser device includes a laser section, a modulator section for modulating the intensity of a laser beam produced by the laser section, and a separation section located between the laser section and the modulator section. The laser section includes a first anode electrode and a first cathode electrode. The modulator section includes a second anode electrode and a second cathode electrode. A lower cladding layer is integral to the laser section, the modulator section, and the separation section and the width of the lower cladding layer is narrowest in the separation section.

### BACKGROUND OF THE INVENTION

1. Field of the Invention

The present invention relates to a modulator integrated laser device for use, e.g., in optical communication systems.

2. Background Art

Japanese Laid-Open Patent Publication No. 2002-277840 discloses a modulator for modulating the intensity of a laser beam. This modulator is driven by both positive and negative phase electrical signals supplied from a driver, in order to improve the extinction ratio. The type of drive system that uses both positive and negative phase electrical signals is referred to as “differential drive.” Japanese Laid-Open Patent Publication No. 2003-17797 also discloses a modulator that is differentially driven.

Japanese Laid-Open Patent Publication Nos. H04-061186 and 2007-158063 disclose modulator integrated laser devices in which a modulator and a laser device are integrated on the same substrate. In the modulator integrated laser device disclosed in the former publication No. 1104-061186, the laser device and the modulator share the same electrodes. In the case of the modulator integrated laser device disclosed in the latter No. 2007-158063, on the other hand, the laser device and the modulator use different separate electrodes.

In some modulator integrated laser devices in which the laser device and the modulator are integrated on the same substrate, it has been found that the voltage applied to the modulator affects the operation of the laser device. Specifically, if the laser device is subjected to the signal voltage of the modulator, the optical output intensity of the laser device is unintentionally modulated. This has been found to degrade the extinction ratio of the optical output of the modulator integrated laser device.

It is also found that if the laser device is subjected to the signal voltage of the modulator, a wavelength chirp is induced in the optical output of the modulator integrated laser device. As a result, when the optical output of the modulator integrated laser device is transmitted through optical fiber over a significant distance, the modulated waveforms arc distorted, resulting in degraded communication quality.

These problems are significant when the modulator is differentially driven. Therefore, it is common to drive the modulator of a modulator integrated laser device by use of either a positive or negative phase electrical signal, but not both (i.e., single phase drive).

### SUMMARY OF THE INVENTION

The present invention has been made to solve the foregoing problems. It is, therefore, an object of the present invention to provide a modulator integrated laser device whose modulator can be differentially driven without any problem.

The features and advantages of the present invention may be summarized as follows.

According to one aspect of the present invention, a modulator integrated laser device includes a laser section, a separation section, and a modulator section which are formed on a same substrate. The laser section has a first lower cladding layer formed on the substrate, an active layer formed on the first lower cladding layer, a first anode electrode formed above the active layer, and a first cathode electrode having a portion in contact with the first lower cladding layer. The separation section has a second lower cladding layer formed on the substrate and in contact with the laser section, and a first absorption layer formed on the second lower cladding layer and connected with the active layer. The modulator section has a third lower cladding layer formed on the substrate and in contact with the separation section, a second absorption layer formed on the third lower cladding layer and connected with the first absorption layer, a second anode electrode formed above the second absorption layer, and a second cathode electrode having a portion in contact with the third lower cladding layer. The substrate is formed of a semi-insulator. The first lower cladding layer, the second lower cladding layer, and the third lower cladding layer are integrally formed with each other. The width of the second lower cladding layer in the transverse direction of the modulator integrated laser device is smaller than the width of the first lower cladding layer and the width of the third lower cladding layer in that direction.

Other and further objects, features and advantages of the invention will appear more fully from the following description.

### BRIEF DESCRIPTION OF THE DRAWINGS

FIG. 1 is a plan view of a modulator integrated laser device in accordance with a first embodiment of the present invention;

FIG. 2 is a cross-sectional view taken along line A-A′ of FIG. 1,

FIG. 3 is a cross-sectional view taken along line B-B of FIG. 1;

FIG. 4 is a cross-sectional view taken along line C-C′ of FIG. 1;

FIG. 5 is a plan view of an optical module having the modulator integrated. laser device mounted thereon;

FIG. 6 is a plan view of the modulator integrated laser device of the second embodiment;

FIG. 7 is a cross-sectional view taken along line C-C′ of FIG. 6;

FIG. 8 is a plan view of the modulator integrated laser device of the third embodiment;

FIG. 9 is a cross-sectional view taken along line A-A′ of FIG. 8;

FIG. 10 is a cross-sectional view taken along line C-C′ of FIG. 8;

FIG. 11 is a cross-sectional view of the separation section of the modulator integrated laser device of the fourth embodiment;

FIG. 12 is a cross-sectional view of a variation of the modulator section of the modulator integrated laser device of the fourth embodiment;

FIG. 13 is a plan view of the modulator integrated laser device of the fifth embodiment;

FIG. 14 is a cross-sectional view taken along line B-B′ of FIG. 13;

FIG. 15 is a cross-sectional view of the separation section of the modulator integrated laser device of the sixth embodiment;

FIG. 16 is a cross-sectional view of a variation of the separation section of the sixth embodiment;

FIG. 17 is a cross-sectional view of another variation of the separation section of the sixth embodiment; and

FIG. 18 is a cross-sectional view of still another variation of the separation section of the sixth embodiment.

### DETAILED DESCRIPTION OF THE PREFERRED EMBODIMENTS

### First Embodiment

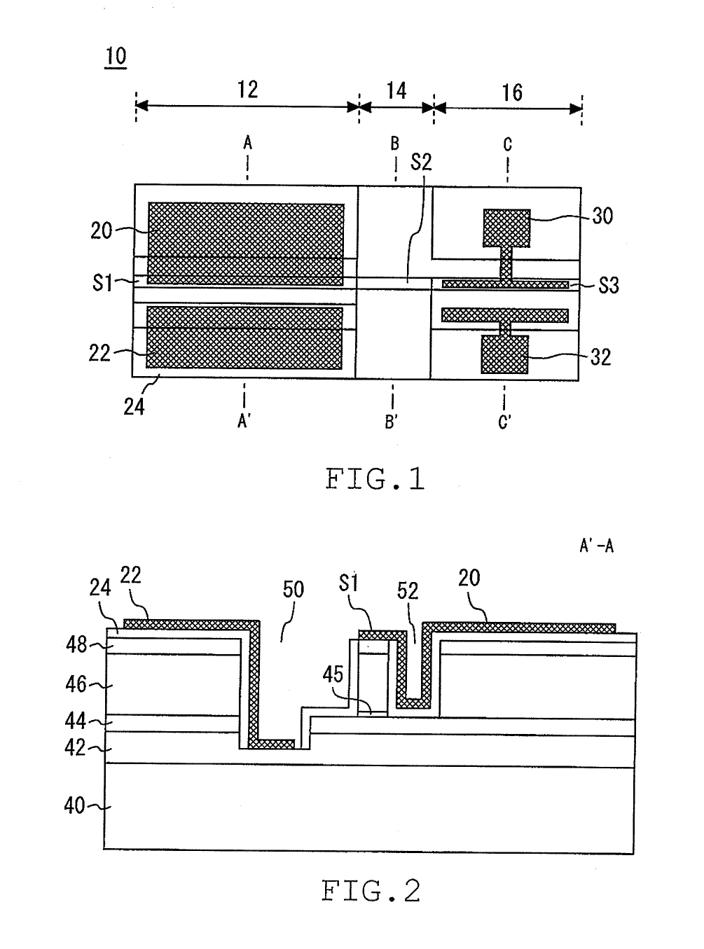

FIG. 1 is a plan view of a modulator integrated laser device in accordance with a first embodiment of the present invention. The modulator integrated laser device 10 is configured by monolithically forming a laser section 12, a separation section 14, and a modulator section 16 on the same substrate. The separation section 14 is in contact at one side with the laser section 12 and at the opposite side with the modulator section 16 so as to separate the laser section 12 and the modulator section 16.

A first anode electrode 20 and a first cathode electrode 22 are formed on the 115 surface of the laser section 12. An SiN film 24 serving as a passivation film is formed on the surface of the laser section 12 in areas where the first anode electrode 20 and the first cathode electrode 22 are not formed. The SiN film 24 is also formed on the surface of the separation section 14. A second anode electrode 30 and a second cathode electrode 32 are formed on the surface of the modulator section 16. The SiN film 24 is also formed on the surface of the modulator section 16 in areas where the second anode electrode 30 and the second cathode electrode 32 are not formed.

A stripe S1 is formed in the laser section 12, a stripe S2 is formed in the separation section 14, and a stripe S3 is formed in the modulator section 16. The stripes S1-S3 together form a linear waveguide. The stripes S1-S3 have a width of approximately 2 μm. The longitudinal dimension of the modulator integrated laser device 10 along the stripes S1-S3 is 700 μm, the transverse dimension of the modulator integrated laser device 10 perpendicular to the stripes is 250 μm, and the thickness dimension is 100 μm.

FIG. 2 is a cross-sectional view taken along line A-A′ of FIG. 1. A cross section of the laser section 12 will be described with reference to FIG. 2. The substrate 40 is formed, e.g., of semi-insulating material such as iron-doped InP. A first lower cladding layer 42 of, e.g., n-type InP is formed on the substrate 40. An active layer 44 having a multiquantum well structure (MQW) of, e.g., InGaAsP is formed on the first lower cladding layer 42. It should be noted that the active layer 44 may be formed of compound semiconductor such as AlGaInAs.

A diffraction grating 45 is formed on the active layer 44 in the stripe S1. A first upper cladding layer 46 of, e.g., p-type InP is formed on the diffraction grating 45, and on the surface of the active layer 44 except for in the stripe S1. A contact layer 48 of, e.g., p-type InGaAs is formed on the first upper cladding layer 46.

On the left side of the stripe S1 is formed a groove 50 extending from the contact layer 48 to the first lower cladding layer 42. The first cathode electrode 22 is configured as two integrally formed portions: a portion in contact with the first lower cladding layer 42 exposed at the bottom surface of the groove 50, and a portion formed on the SiN film 24 on the contact layer 48. Thus, a portion of the first cathode electrode 22 is in contact with the first lower cladding layer 42.

A groove 52 for forming the stripe SI is formed on the right side of the stripe S1. The first anode electrode 20 has three portions: a portion in contact with the top surface of the contact layer 48 at the top of the stripe S1, a portion formed to extend on the SiN film 24 along the groove 52, and a portion formed on the SiN film 24 on the contact layer 48. All portions of the first anode electrode 20 are formed above the active layer 44. Thus, the laser section 12 has a distributed feedback laser device formed therein.

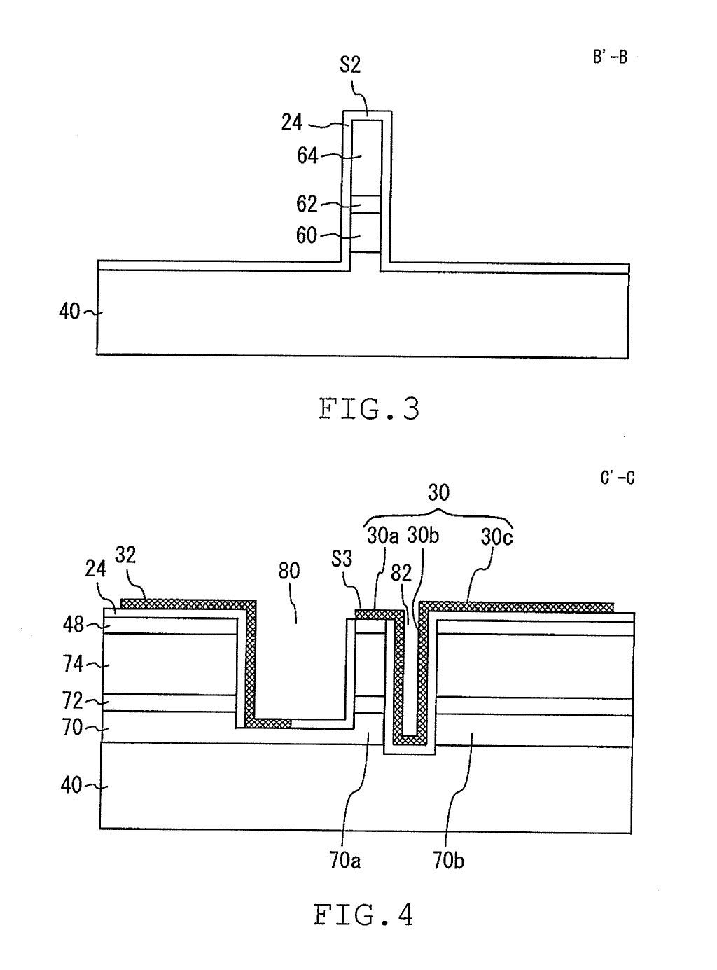

FIG. 3 is a cross-sectional view taken along line B-B′ of FIG. 1. A cross section of the separation section 14 will be described with reference to FIG. 3. The stripe S2 is formed on the substrate 40. The stripe S2 includes a second lower cladding layer 60 of e.g., n-type InP formed on the substrate 40. A first absorption layer 62 is formed on the second lower cladding layer 60. It should be noted that the second lower cladding layer 60 is formed only directly under the first absorption layer 62 in order to reduce the width of the second lower cladding layer 60.

The first absorption layer 62 is formed so as to be connected with the active layer 44 in the stripe S1. The first absorption layer 62 is formed of a multiquantum well structure (MQW) of, e.g., AlGaInAs. It should be noted that the first absorption layer 62 may be formed of compound semiconductor such as InGaAsP.

A second upper cladding layer 64 of, e.g., p-type MP is formed on the first absorption layer 62. Thus, the stripe S2 is made up of the second lower cladding layer 60, the first absorption layer 62, and the second upper cladding layer 64. The stripe S2 is a so-called high-mesa optical waveguide, since the first absorption layer 62, which serves as a core layer, is formed by etching. The entire surface of the separation section 14 is covered with the SiN film 24. An electrode is not formed on the surface of the separation section 14.

FIG. 4 is a cross-sectional view taken along line C-C′ of FIG. 1. A cross section of the modulator section 16 will be described with reference to FIG. 4. A third lower cladding layer 70 of, e.g., n-type InP is formed on the substrate 40. A second absorption layer 72 is formed on the third lower cladding layer 70. The second absorption layer 72 is formed so as to be connected with the first absorption layer 62 described above. The second absorption layer 72 is formed of the same material as the first absorption layer 62.

A third upper cladding layer 74 of, e.g., p-type InP is formed on the second absorption layer 72. A contact layer 48 is formed on the third upper cladding layer 74.

The stripe S3 is a so-called high-mesa. optical waveguide, since the second absorption layer 72, which serves as a core layer, is formed by etching. On the left side of the stripe S3 is formed a groove 80 extending from the contact layer 48 to the third lower cladding layer 70. The second cathode electrode 32 is configured as two integrally formed portions: a portion in contact with the third lower cladding layer 70 exposed at the bottom surface of the groove 80, and a portion formed on the SiN film 24 on the contact layer 48. Thus, the formation of the groove 80 allows a portion of the second cathode electrode 32 to be in contact with the third lower cladding layer 70.

On the right side of the stripe S3 is formed a groove 82 extending from the surface of the modulator section 16 to at least the substrate 40. The SiN film 24 is formed along the wall surfaces of the groove 82. The third lower cladding layer 70 is divided by the groove 82 into a portion 70a directly under the second absorption layer 72 (referred herein to as the under-the-second-absorption-layer portion 70a) and a separated portion 70b. The separated portion 70b is separated from the under-the-second-absorption-layer portion 70a by the groove 82. This separated portion 70b is isolated from the second lower cladding layer 60 of the separation section 14 and the first lower cladding layer 42 of the laser section 12.

The second anode electrode 30 has an above-the-second-absorption-layer portion 30a, a groove portion 30b, and a wire bonding portion 30c. The above-the-second-absorption-layer portion 30a is formed above the-under-the second-absorption-layer portion 70a in the stripe S3. The groove portion 30b is formed on the insulating film (SiN film 24) along the wall surfaces of the groove 82. The wire bonding portion 30c is formed above the separated portion 70b. Specifically, this wire bonding portion 30c is formed above the second absorption layer 72. Further, a third upper cladding layer 74 is formed between the second absorption layer 72 and the wire bonding portion 30c.

Thus, in the modulator integrated laser device 10 of the first embodiment, the active layer 44, the first absorption layer 62, and the second absorption layer 72 together form a stripe-shaped waveguide having a uniform width. The layers of this structure may have, e.g., the following thicknesses: the substrate 40, 100 μm; the first lower cladding layer 42, the second lower cladding layer 60, and the third lower cladding layer 70, 0.5 μm; the active layer 44, 0.3 μm; the first absorption layer 62 and the second absorption layer 72, 0.3 μm; the first upper cladding layer 46, the second upper cladding layer 64, and the third upper cladding layer 74, 2 μm; and the contact layers 48, 0.5 μm.

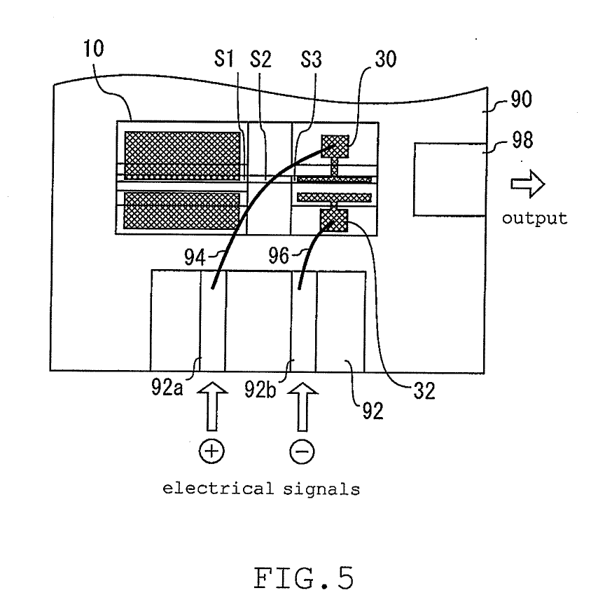

The operation of the modulator integrated laser device 10 will now be described with reference to FIG. 5. FIG. 5 is a plan view of an optical module having the modulator integrated laser device 10 mounted thereon. The optical module 90 has a transmission line substrate 92. An electrode 92a and an electrode 92b are formed on the transmission line substrate 92. The electrode 92a is connected to the second anode electrode 30 by a wire 94. The electrode 92b is connected to the second cathode electrode 32 by a wire 96.

In operation, a laser beam is emitted from the laser section 12 and enters the modulator section 16. Modulation signals are applied to the electrodes 92a and 92b, wherein these modulation signals are high-frequency positive and negative phase electrical signals which differ only in phase (specifically, they have a 180° phase difference between them). That is, differential signals are applied to the electrodes 92a and 92b. Since the amount of laser light absorbed by the modulator section 16 varies with the voltage difference between these differential signals, the intensity of the laser beam output through an optical coupling system 98 can be modulated.

The following three features of the modulator integrated laser device 10 of the first embodiment enhance the isolation resistance between the laser section 12 and the modulator section 16. A first feature is that the first anode electrode 20, the first cathode electrode 22, the second anode electrode 30, and the second cathode electrode 32 are formed separately from one another. For example, if the first cathode electrode 22 and the second cathode electrode 32 are replaced by a single common cathode electrode, the voltage applied to the modulator section will affect the operation of the laser section. Therefore, the electrodes of the laser section are formed separately from the electrodes of the modulator section in order to avoid such problems.

A second feature is that the substrate 40 is formed of semi-insulating material, e.g., iron-doped InP. This prevents electrical connection of the laser section 12 to the modulator section 16 through the substrate 40.

A third feature is that the second lower cladding layer 60 of the separation section 14 is configured to be small (or narrow) and the separation section 14 does not include a contact layer. The second lower cladding layer 60 has a low electrical resistivity, since it is formed of n-type InP. Therefore, in order to increase the isolation resistance between the laser section 12 and the modulator section 16, it is preferable to reduce the cross section of the second lower cladding layer 60, which connects the first lower cladding layer 42 to the third lower cladding layer 70. In the modulator integrated laser device 10 of the first embodiment, the separation section 14 includes only the stripe S2 formed on the substrate 40 and, as a result, the second lower cladding layer 60 is very small in cross section, thereby enhancing the isolation resistance between the laser section 12 and the modulator section 16.

Further, the separation section 14 is not provided with an electrode, eliminating the need for a contact layer. Since the separation section 14 does not have a contact layer, the contact layer 48 of the laser section 12 is separated from the contact layer 48 of the modulator section 16. This separation increases the isolation resistance between the laser section 12 and the modulator section 16.

These three features serve to substantially reduce the influence on the laser section 12 from the electrical signals used to differentially drive the modulator section 16, thereby enhancing the electrical separation of the laser section 12 from the modulator section 16. Particularly, it is possible to enhance the electrical separation of the first cathode electrode 22 from the second cathode electrode 32. This makes it possible to differentially drive the modulator section while improving the extinction ratio of the output beam of the modulator integrated laser device 10 and minimizing the wavelength chirp in the output beam. It should be noted that the advantages of the differential drive of the modulator section 16 include the improvement of the extinction ratio, and the ability to drive the modulator section using a low amplitude of voltage (as compared with single phase drive). The driving of the modulator section using a low amplitude of voltage allows for power saving and the use of a low-cost driver. Thus, in the modulator integrated laser device 10 of the first embodiment, the modulator section 16 can be differentially driven without any problem.

Incidentally, an anode electrode typically has a large wire bonding portion (approximately 50 μm square). Therefore, a large capacitance is formed between the wire bonding portion and the underlying lower cladding layer, which has in the past prevented high speed operation of the modulator section. In such cases, the upper cladding layer, etc. intermediate between the lower cladding layer and the wire bonding portion acts as dielectric.

In the first embodiment, on the other hand, the separated portion 70b, which is the portion of the third lower cladding layer 70 below the wire bonding portion 30c, is surrounded by side faces of the modulator integrated laser device 10, the groove 82 (which extends in depth to the substrate 40), and the space on one side of the stripe S2 where the second lower cladding layer 60 is not formed. That is, the separated portion 70b has cross sections in direction of edge face of the device 10, side face of the groove 82, and the separation section 14. Therefore, the separated portion 70b, which is the portion of the third lower cladding layer 70 below the wire bonding portion 30c, is electrically separated from the under-the-second-absorption layer portion 70a, which is the portion of the third lower cladding layer 70 below the stripe S3 and to which a voltage is applied from the second cathode electrode 32. As a result, a substantial capacitance is unlikely to be formed between the wire bonding portion 30c and the separated portion 70b, allowing the modulator section 16 to operate at high speed.

In the case of the device disclosed in the above Japanese Laid-Open Patent Publication No. 2007-158063, the insulating separation section (or separation region) is formed by implantation of ions, which is considered to result in unintended implantation of ions in the active layer and hence decreased reliability of the device. In the first embodiment of the present invention, on the other hand, there is no possibility of the active layer being implanted with ions, meaning that the modulator integrated laser device of the first embodiment has higher reliability than the device disclosed in the above publication.

Further, the upper cladding layer in the separation section (or separation region) disclosed in the above publication is formed to be of opposite conductivity type to the upper cladding layers in the laser section (or LD region) and the modulator section (or EA region), and the lower cladding layer in the separation section (or separation region) is formed to be of opposite conductivity type to the lower cladding layers in the laser section (or LD region) and the modulator section (or EA region). The formation of such a separation section requires a removal process and a regrowth process, and furthermore it is considered difficult to adequately increase the electrical resistance between the separation section and the modulator section (or EA region). The first embodiment of the present invention, on the other hand, does not require a removal process and a regrowth process fur forming a separation section. Furthermore, the separated portion 70b is electrically isolated, thereby increasing the electrical resistance between the modulator section (the separated portion 70b) and the separation section.

The modulator integrated laser device 10 of the first embodiment has three features for enhancing the electrical separation of the laser section 12 from the modulator section 16. However, in other embodiments, only one of these features may be adopted to enhance the electrical separation. Various other alterations may be made to the first embodiment while retaining the features of the present invention. For example, the SiN film 24 may be replaced by other insulating films.

### Second Embodiment

A modulator integrated laser device in accordance with a second embodiment of the present invention has many features common to the modulator integrated laser device of the first embodiment. Therefore, the following description of the modulator integrated laser device of the second embodiment will be primarily limited to the differences from the modulator integrated laser device of the first embodiment.

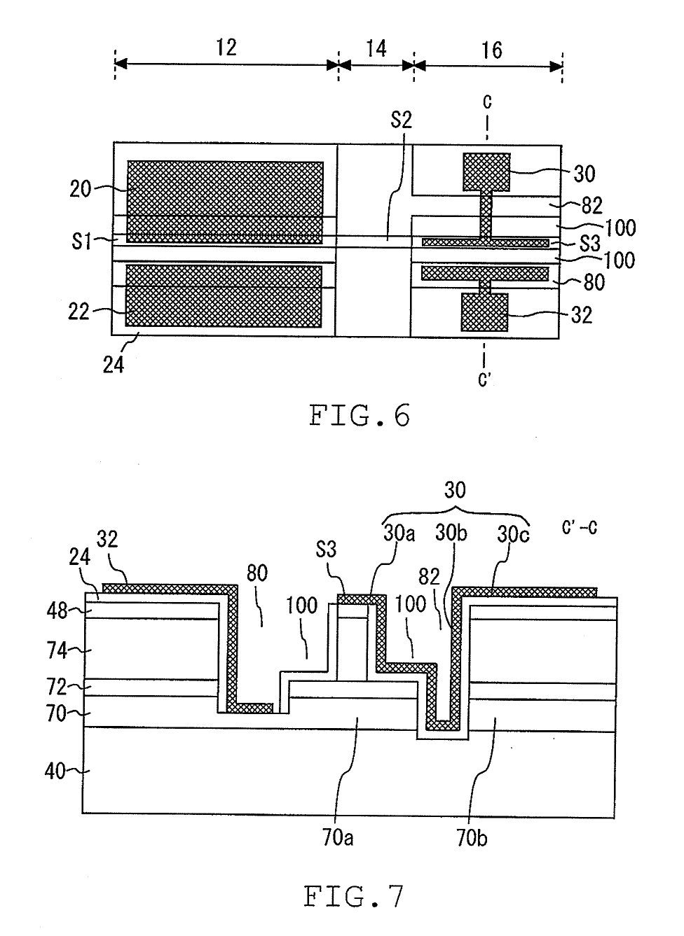

FIG. 6 is a plan view of the modulator integrated laser device of the second embodiment. This modulator integrated laser device differs from that of the first embodiment in terms of the structure of the modulator section 16. A recessed portion 100 is formed along both sides of the stripe S3. The top surfaces of the recessed portions 100 are lower than the top surface of the stripe S3, but higher than the bottom surfaces of the grooves 80 and 82. It should be noted that this modulator integrated laser device has the same longitudinal, transverse, and thickness dimensions as the modulator integrated laser device of the first embodiment.

FIG. 7 is a cross-sectional view taken along line C-C′ of FIG. 6. In the stripe S3, the third upper cladding layer 74 and the contact layer 48 have the same width, but the second absorption layer 72 has a greater width than these layers. That is, the stripe S3 is an optical waveguide of the ridge type. Thus, the modulator section 16 is configured from an optical ridge waveguide, which still makes it possible to achieve the same advantages as described above in connection with the modulator integrated laser device of the first embodiment.

### Third Embodiment

A modulator integrated laser device in accordance with a third embodiment of the present invention has many features common to the modulator integrated laser device of the first embodiment. Therefore, the following description of the modulator integrated laser device of the third embodiment will be primarily limited to the differences from the modulator integrated laser device of the first embodiment.

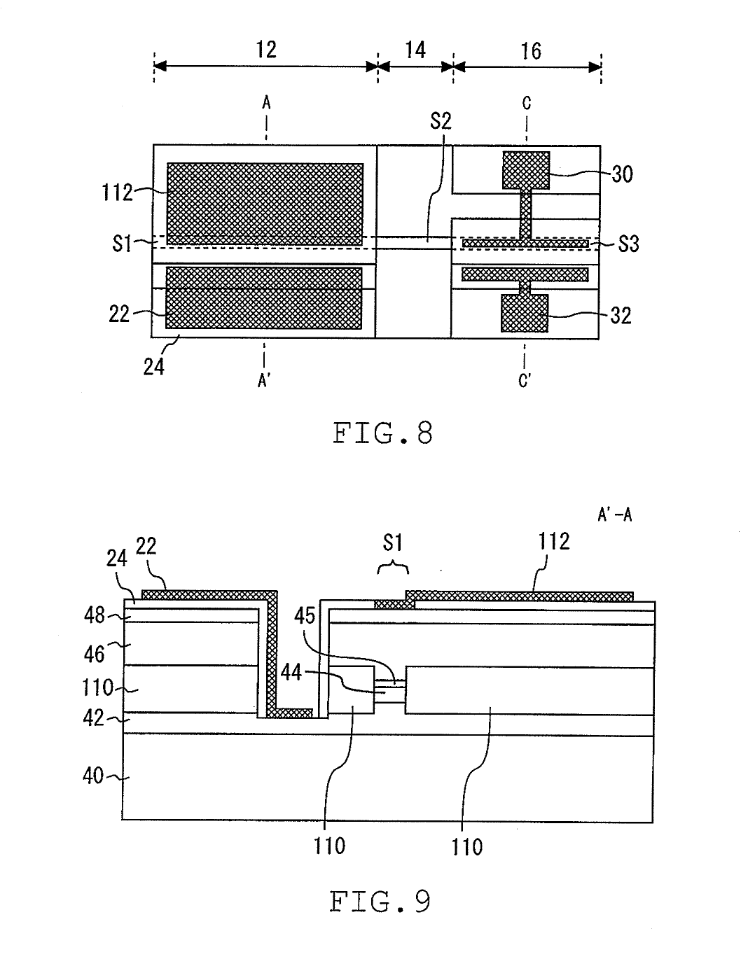

FIG. 8 is a plan view of the modulator integrated laser device of the third embodiment. This modulator integrated laser device differs from that of the first embodiment in terms of the structures of the laser section 12 and the modulator section 16. The top of the first stripe S1, which is indicated by dashed lines in FIG. 8, is level with the SiN film 24 on both sides. The third stripe S3 is also indicated by dashed lines, and its top is level with the SiN film 24 on both sides. It should be noted that this modulator integrated laser device has the same longitudinal, transverse, and thickness dimensions as the modulator integrated laser device of the first embodiment.

FIG. 9 is a cross-sectional view taken along line A-A′ of FIG. 8. In the stripe S1, a semi-insulator 110 is formed on both sides of a portion of the first lower cladding layer 42, the active layer 44, the diffraction grating 45, and a portion of the first upper cladding layer 46. The semi-insulators 110 are formed of iron-doped InP. This structure is a so-called buried structure and includes an optical waveguide in which the active layer 44 serving as a core is covered or surrounded by the substrate 40, the first lower cladding layer 42, the diffraction grating 45, the first upper cladding layer 46, and the semi-insulators 110.

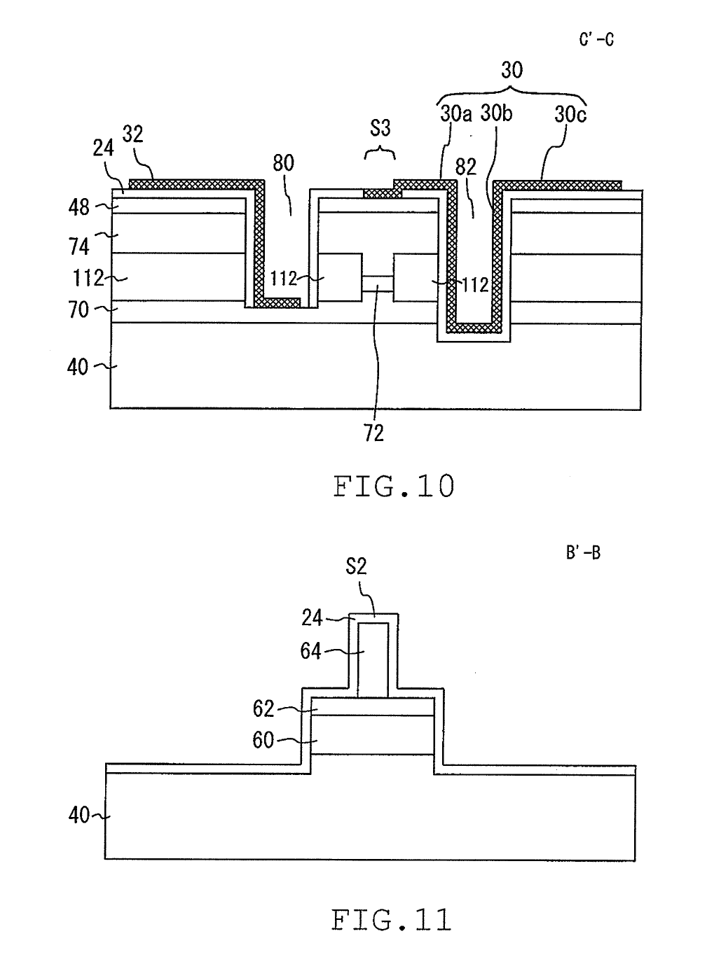

The first anode electrode 20 is formed to be flat and in contact with the top surface of the stripe S1. FIG. 10 is a cross-sectional view taken along line C-C′ of FIG. 8. The second absorption layer 72 of the modulator section 16 is buried or surrounded by semi-insulators 112. The semi-insulators 110 and 112 have a thickness of 2 μm. Thus, the active layer 44 and the second absorption layer 72 are buried or surrounded by the semi-insulators 110 and 112, respectively, which still makes it possible to achieve the same advantages as described above in connection with the modulator integrated laser device of the first embodiment.

### Fourth Embodiment

A modulator integrated laser device in accordance with a fourth embodiment of the present invention has many features common to the modulator integrated laser device of the first embodiment. Therefore, the following description of the modulator integrated laser device of the fourth embodiment will be primarily limited to the differences from the modulator integrated laser device of the first embodiment.

FIG. 11 is a cross-sectional view of the separation section of the modulator integrated laser device of the fourth embodiment. In the stripe S2, the first absorption layer 62 and the second lower cladding layer 60 have the same width, but the second upper cladding layer 64 has a smaller width than these layers. The second upper cladding layer 64 has a width of 2 μm, and the first absorption layer 62 and the second lower cladding layer 60 have a width of 10 μm. It should be noted that this modulator integrated laser device has the same longitudinal, transverse, and the thickness dimensions as the modulator integrated laser device of the first embodiment.

The stripe S2 is an optical waveguide of the low mesa ridge type. Since the width of the modulator integrated laser device is 250 μm and the width of the first absorption layer 62 is 10 μm, the sum of the widths of the areas extending along both sides of the first absorption layer 62 is 240 μm. This means that the second lower cladding layer 60 (which underlies the first absorption layer 62) is not formed on these wide areas.

Since the width of the first absorption layer 62 (10 μm) is substantially greater than the width of the optical waveguide, i.e., the width of the stripes S1-S3 (2 μm), light confinement within the low mesa ridge optical waveguide is not interfered with. Further, the second lower cladding layer 60 occupies only a slight portion of the width of the modulator integrated laser device, that is, the width of the second lower cladding layer 60 is only 10 μm whereas the width of the device is 250 μm. This means that, although the second lower cladding layer 60 has a greater width than the optical waveguide, the cross section of the second lower cladding layer 60 is still small, making it possible to increase the isolation resistance between the laser section and the modulator section. It should be noted that the modulator section of the fourth embodiment may be employed in the modulator integrated laser devices of the second and third embodiments.

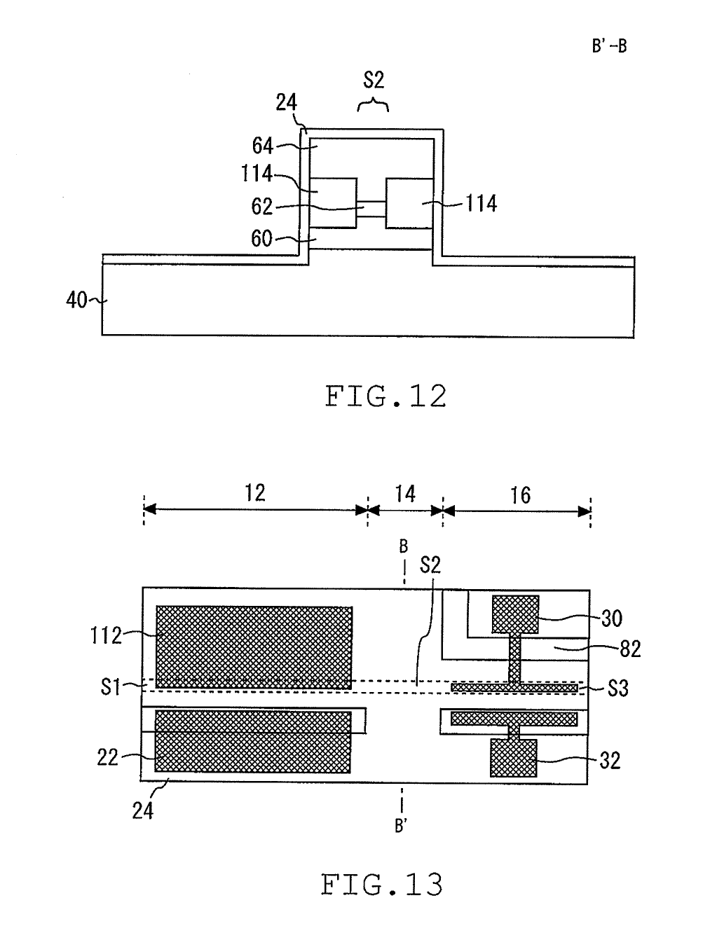

FIG. 12 is a cross-sectional view of a variation of the modulator section of the modulator integrated laser device of the fourth embodiment. In this modulator section, the first absorption layer 62 has a width of 2 μm and is buried or surrounded by semi-insulators 114. The combined width of the first absorption layer 62 and the semi-insulators 114 is equal to the width of the second upper cladding layer 64 and the width of the second lower cladding layer 60. Since the width of the second lower cladding layer 60 is 10 μm and the width of the modulator integrated laser device is 250 μm, the sum of widths of the areas extending along the outer sides of the semi-insulators 114 (serving as burying layers) is 240 μm. This means that the second lower cladding layer is not formed on these wide areas.

The construction of this modulator integrated laser device makes it possible to reduce the cross section of the second lower cladding layer 60 without interfering with light confinement within the optical waveguide, as well as to increase the isolation resistance between the laser section 12 and the modulator section 16.

### Fifth Embodiment

A modulator integrated laser device in accordance with a fifth embodiment of the present invention has many features common to the modulator integrated laser device of the third embodiment. Therefore, the following description of the modulator integrated laser device of the fifth embodiment will be primarily limited to the differences from the modulator integrated laser device of the third embodiment.

FIG. 13 is a plan view of the modulator integrated laser device of the fifth embodiment. The tops of the stripes S1-S3 of the device, which are indicated by dashed lines in FIG. 13, are level with the SiN film 24 on both sides. The modulator integrated laser device of the fifth embodiment differs from that of the third embodiment in terms of the structures of the separation section 14 and the modulator section 16. The surface of the separation section is formed to be flat. The groove 82 in the modulator section 16 is formed to have an L-shape.

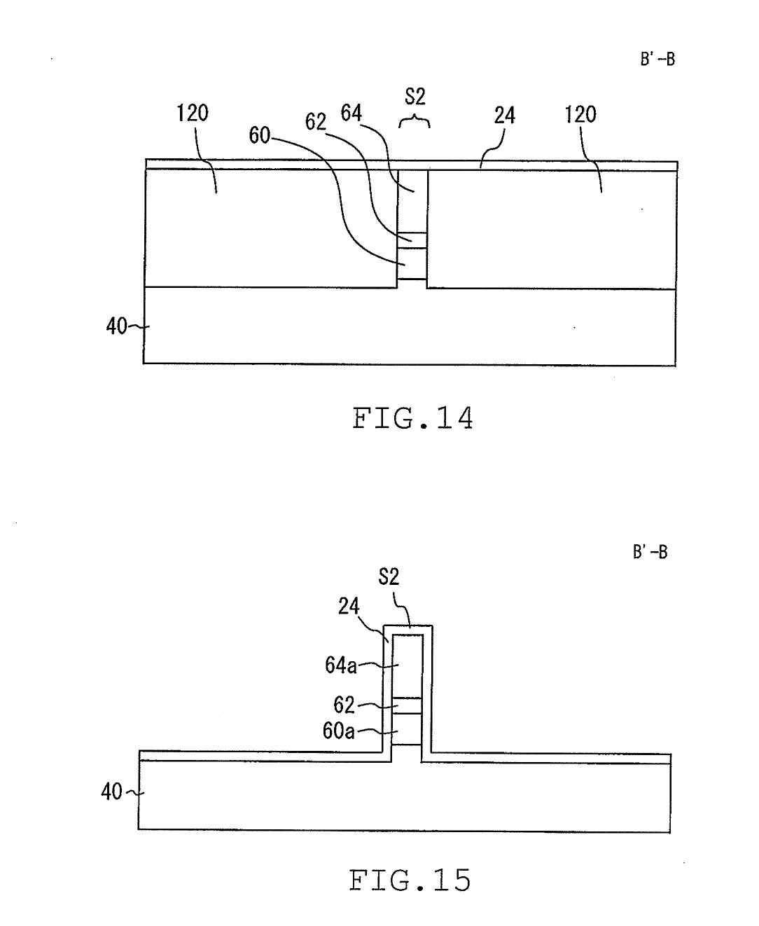

FIG. 14 is a cross-sectional view taken along line B-B of FIG. 13. The width of the first absorption layer 62 is 2 μm. The first absorption layer 62 is buried or surrounded by semi-insulators 120. The thickness of the semi-insulators 120 is 3 μm. The second upper cladding layer 64 and the second lower cladding layer 60 are formed only in the stripe S2. It should be noted that this modulator integrated laser device has the same longitudinal, transverse, and thickness dimensions as the modulator integrated laser device of the first embodiment.

The modulator integrated laser device of the fifth embodiment is configured in such a manner that the cores in the stripes S1-S3 are buried or surrounded by semi-insulators. This structure, like that described in connection with the first embodiment, enables the laser section 12 to be electrically separated from the modulator section 16. It should be noted that since the groove 82 in the modulator section 16 is formed to have an L-shape, the separated portion 70b of the third lower cladding layer is separated from the semi-insulators 120 in the separation section 14, as well as from the under-the-second-absorption-layer portion 70a. As a result, it is possible to reduce the capacitance of the parasitic capacitor formed between the separated portion 70b and the overlying wire bonding portion 30c, which act as electrodes, thereby allowing the modulator section 16 to operate at high speed.

Although in the fifth embodiment the first absorption layer 62 is buried or surrounded by the semi-insulators 120, it is to be understood that it may be buried or surrounded by an n-type or p-type InP layer having a carrier concentration of 1×10¹⁷ cm⁻³ or less. Further, the modulator integrated laser device may be configured in such a manner that at least one layer among the active layer and the first and second absorption layers may be buried or covered on sides extending in the direction of travel of the light. In such cases also, the burying or covering may be accomplished by use of a semi-insulator or any suitable layer having a carrier concentration of 1×10¹⁷ cm³ or less.

### Sixth Embodiment

A modulator integrated laser device in accordance with a sixth embodiment of the present invention is characterized by having a separation section firmed of particular material. The laser section and the modulator section of this modulator integrated laser device may be identical to those disclosed in connection with one of the first to fourth embodiments.

FIG. 15 is a cross-sectional view of the separation section of the modulator integrated laser device of the sixth embodiment. The second lower cladding layer 60a of this separation section is formed of a semi-insulator containing InP, or an n-type or p-type InP layer having a carrier concentration of 1×10¹⁷ cm⁻³ or less. The second upper cladding layer 64a of this separation section is also formed of a semi-insulator, or an n-type or p-type InP layer having a carrier concentration of 1×10¹⁷ cm⁻³ or less.

In the separation section 14, the second lower cladding layer, the first absorption layer, and the second upper cladding layer are formed only in the stripe S2; these layers are not formed in other portions of the separation section 14. The separation section 14 of the sixth embodiment differs from that shown in FIG. (described in connection with the first embodiment) in that the second lower cladding layer and the second upper cladding layer are formed of a semi-insulator or an n-type or p-type InP layer having a carrier concentration of 1×10¹⁷ cm⁻³ or less.

Thus, in the modulator integrated laser device of the sixth embodiment, the second lower cladding layer 60a and the second upper cladding layer 64a in the separation section 14 are formed of high resistivity material, thereby enhancing the electrical separation of the laser section 12 from the modulator section 16.

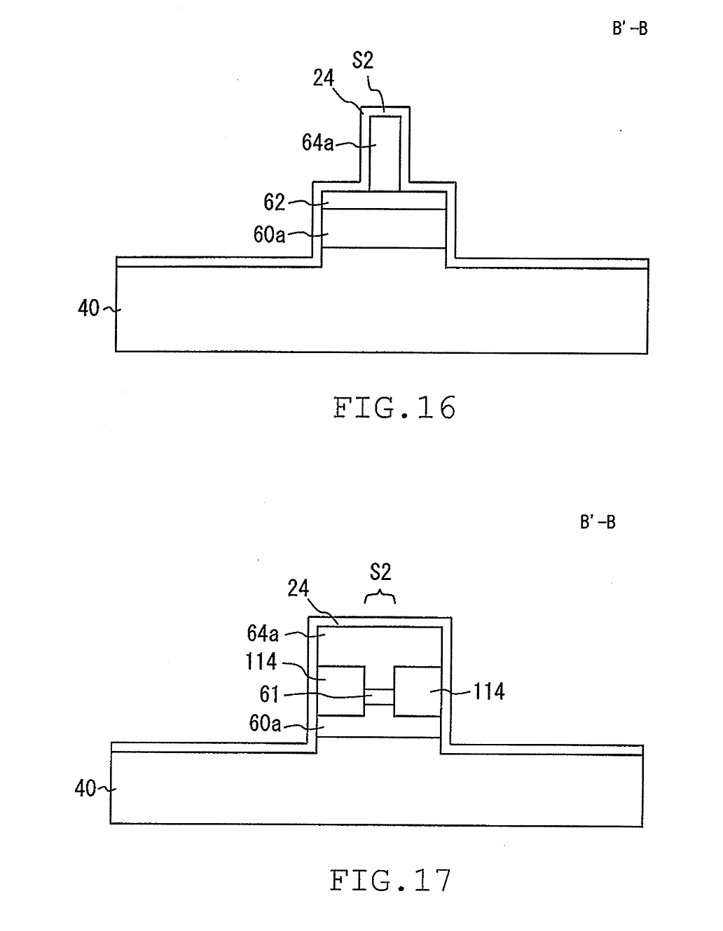

FIG. 16 is a cross-sectional view of a variation of the separation section of the sixth embodiment. In this separation section, the second lower cladding layer 60a and the second upper cladding layer 64a are formed of a semi-insulator or an n-type or p-type InP layer having a carrier concentration of 1×10¹⁷ cm⁻³ or less. This separation section is similar to that shown in FIG. 11, except that, as described above, the second lower cladding layer and the second upper cladding layer are formed of different material than that of the second lower cladding layer and the second upper cladding layer shown in FIG. 11.

FIG. 17 is a cross-sectional view of another variation of the separation section of the sixth embodiment. In this separation section, the second lower cladding layer 60a and the second upper cladding layer 64a are formed of a semi-insulator or an n-type or p-type InP layer having a carrier concentration of 1×10¹⁷ cm⁻³ or less. This separation section is similar to that shown in FIG. 12, except that, as described above, the second lower cladding layer and the second upper cladding layer are formed of different material than that of the second lower cladding layer and the second upper cladding layer shown in FIG. 12.

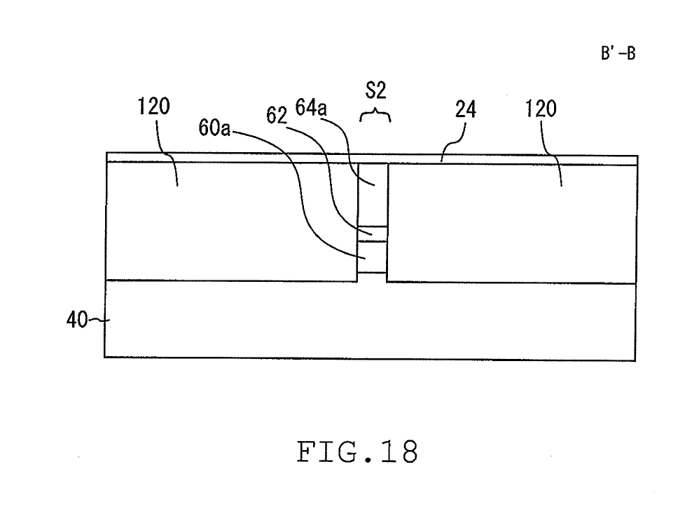

FIG. 18 is a cross-sectional view of still another variation of the separation section of the sixth embodiment. In this separation section, the second lower cladding layer 60a and the second upper cladding layer 64a are formed of a semi-insulator or an n-type or p-type InP layer having a carrier concentration of 1×10¹⁷ cm⁻³ or less. This separation section is similar to that shown in FIG. 14, except that, as described above, the second lower cladding layer and the second upper cladding layer are formed of different material than that of the second lower cladding layer and the second upper cladding layer shown in FIG. 14.

Although in the sixth embodiment both the second upper cladding layer and the second lower cladding layer are formed of a semi-insulator, etc., it is to be understood that only either the second upper cladding layer or the second lower cladding layer may be formed of a semi-insulator or an n-type or p-type layer having a concentration of 1×10¹⁷ cm⁻³ or less, which still enables the laser section 12 to be electrically separated from the modulator section 16.

Further, since the first lower cladding layer, the second lower cladding layer, and the third lower cladding layer are integrally formed with each other, the electrical separation of the laser section from the modulator section is enhanced by the fact that the width of the second lower cladding layer (60a) in the transverse direction of the modulator integrated laser device is smaller than the widths of the first and third lower cladding layers in that direction.

Various alterations may be made to the modulator integrated laser devices of the present invention. For example, features of the modulator integrated laser devices of embodiments described above may be combined where appropriate. Further, the conductivity types of the layers of the modulator integrated laser devices may be reversed where appropriate, or other semiconductor layers may be added to these devices.

The modulator integrated laser device of the present invention has an increased isolation resistance between its laser section and modulator section, so that the modulator can be differentially driven without any problem.

Obviously many modifications and variations of the present invention are possible in the light of the above teachings. It is therefore to be understood that within the scope of the appended claims the invention may be practiced otherwise than as specifically described.

The entire disclosure of Japanese Patent Application No. 2012-092904, filed on Apr. 16, 2012, including specification, claims, drawings, and summary, on which the Convention priority of the present application is based, is incorporated herein by reference in its entirety.

1. An integrated optical modulator and laser device comprising:
a substrate of a semi-insulating material,
a laser section on said substrate,
a separation section on said substrate, and
a modulator section on said substrate, wherein
said laser section has a first lower cladding layer on said substrate, an active layer on said first lower cladding layer, a first anode electrode located opposite said active layer, and a first cathode electrode having a portion in contact with said first lower cladding layer,
said separation section has a second lower cladding layer on said substrate and in contact with said laser section, and a first absorption layer on said second lower cladding layer and connected to said active layer,
said second lower cladding layer is a semi-insulating material or a layer having a carrier concentration not exceeding 1×10¹⁷ cm⁻³,
said modulator section has a third lower cladding layer on said substrate and in contact with said separation section, a second absorption layer on said third lower cladding layer and connected to said first absorption layer, a second anode electrode located opposite said second absorption layer, and a second cathode electrode having a portion in contact with said third lower cladding layer,
said first lower cladding layer, said second lower cladding layer, and said third lower cladding layer are integrated with each other, and
said second lower cladding layer has a width in the transverse direction of said modulator integrated laser device that is smaller than width of said first lower cladding layer and width of said third lower cladding layer in the transverse direction of said modulator integrated laser device.

2. The integrated optical modulator and laser device according to claim 1, wherein:
said active layer, said first absorption layer, and said second absorption layer, together, define a stripe-shaped waveguide having a uniform width; and
said second lower cladding layer is located only directly opposite said first absorption layer.

3-4. (canceled)

5. An integrated optical modulator and laser device comprising:
a substrate of a semi-insulating material,
a laser section on said substrate,
a separation section on said substrate, and
a modulator section on said substrate, wherein
said laser section has a first lower cladding layer on said substrate, an active layer on said first lower cladding layer, a first anode electrode located opposite said active layer, a first cathode electrode having a portion in contact with said first lower cladding layer, and a first upper cladding layer between said active layer and said first anode electrode,
said separation section has a second lower cladding layer on said substrate and in contact with said laser section, a first absorption layer on said second lower cladding layer and connected to said active layer, and a second upper cladding layer on said first absorption layer
said modulator section has a third lower cladding layer on said substrate and in contact with said separation section, a second absorption layer on said third lower cladding layer and connected to said first absorption layer, a second anode electrode located opposite said second absorption layer, a second cathode electrode having a portion in contact with said third lower cladding layer, and a third upper cladding layer between said second absorption layer and said second anode electrode wherein said second upper cladding layer or said second lower cladding layer is a semi-insulating material or a layer having a carrier concentration not exceeding 1×10¹⁷ cm⁻³.
said first lower cladding layer, said second lower cladding layer, and said third lower cladding layer are integrated with each other, and
said second lower cladding layer has a width in the transverse direction of said modulator integrated laser device that is smaller than width of said first lower cladding layer and width of said third lower cladding layer in the transverse direction of said modulator integrated laser device

6. The integrated optical modulator and laser device according to claim 1, wherein:
said third lower cladding layer has an under-the-second-absorption-layer portion directly under said second absorption layer, and a separated portion separated from said under-the-second-absorption-layer portion by a groove extending from a surface of said modulator section to at least said substrate;
said modulator integrated laser device includes an insulating film along a wall surface of said groove;
said second anode electrode has an above-the-second-absorption-layer portion above said second absorption layer, a groove portion along said insulating film, and a wire bonding portion above said separated portion; and
said separated portion is isolated from said second lower cladding layer.

7. The integrated optical modulator and laser device according to claim 5, wherein:
said active layer, said first absorption layer, and said second absorption layer, together, define a stripe-shaped waveguide having a uniform width; and
said second lower cladding layer is located only directly opposite said first absorption layer.

8. The integrated optical modulator and laser device according to claim 5, wherein:
said third lower cladding layer has an under-the-second-absorption-layer portion directly under said second absorption layer, and a separated portion separated from said under-the-second-absorption-layer portion by a groove extending from a surface of said modulator section to at least said substrate;
said modulator integrated laser device includes an insulating film along a wall surface of said groove;
said second anode electrode has an above-the-second-absorption-layer portion above said second absorption layer, a groove portion along said insulating film, and a wire bonding portion above said separated portion; and
said separated portion is isolated from said second lower cladding layer.
